(19) United States
(12) Patent Application Publication
(10) Pub. No.: US 2020/0367367 A1
(43) Pub. Date: Nov. 19, 2020

(54) Method and Apparatus for Stacking Printed Circuit Board Assemblies with Single Reflow

(71) Applicant: Jabil Inc., St. Petersburg, FL (US)

(72) Inventors: Zambri Bin Samsudin, Penang (MY); Idris Bin Mansor, Penang (MY)

(73) Assignee: Jabil Inc., St. Petersburg, FL (US)

(21) Appl. No.: 16/413,046

(22) Filed: May 15, 2019

(51) Int. Cl. H05K 3/36; H05K 3/34; B23K 1/00; B23K 37/04

(52) U.S. Cl. CPC H05K 3/368; H05K 3/3421; H05K 3/3484; B23K 2101/42; B23K 37/04; H05K 2203/1484; H05K 2203/16; B23K 1/0016

(57) ABSTRACT

Disclosed herein are implementations of methods and devices for stacking printed circuit board (PCB) assemblies (PCBA) with a single reflow process which decreases impact on surface mount technology (SMT) component and solder joint reliability. A method includes transferring solder paste on to a bottom PCB and forming a bottom PCBA by placing SMT components on the bottom PCB. A middle PCB is stacked on the bottom PCBA and solder paste is transferred on to the middle PCB. A top PCB is stacked on the middle PCB and solder paste is transferred on to the top PCB. SMT components are placed on the top PCB to form a stacked assembly. The stacked assembly is reflowed in a single reflow so that all solder paste simultaneously or nearly simultaneously melts to bond SMT components to respective PCB boards and to bond respective PCBs to each other.

### TECHNICAL FIELD

This disclosure relates to electronics and electronics assembly processing.

### BACKGROUND

Stacking of printed circuit board assemblies (PCBAs) on a mother or main board suffers from multiple issues. The PCBAs (which are also known as the daughter boards) may be assembled offline. This incurs longer cycle-times. The offline assembled PCBAs are then later treated as a surface mount technology (SMT) component during the main board assembly process. That is, the PCBAs are subjected to multiple thermal excursions (depending on the stack count) for each reflow process of the main board assembly process. Designers must therefore select components that can stand multiple heat excursions due to multiple reflow processes. In addition, the multiple reflow processes may weaken joint bonds including mechanical and electrical connectivity. Alternatively, single reflow process can be abducted by depositing the solder paste on the daughter board via a jetting process. This process not only requires a massive capital investment on a jetting machine, but the constraint on the deposition size is limited to a 0.5 mm dot size (standard option) and a 0.3 mm dot size (special option), making this method unsuitable for packages smaller then a 0201 package size (which is a pad size of 0.3 mm×0.38 mm).

### SUMMARY

Disclosed herein are implementations of methods and devices for stacking printed circuit board assemblies with a single reflow process. This decreases impact on surface mount technology (SMT) component and solder joint reliability. In addition, the processes are suitable for packages smaller than the 0201-package size. A method includes transferring solder paste on to a bottom PCB and forming a bottom PCBA by placing surface mount technology (SMT) components on the bottom PCB. A middle PCB is stacked on the bottom PCBA and solder paste is transferred on to the middle PCB. A top PCB is stacked on the middle PCB and solder paste is transferred on to the top PCB. SMT components are placed on the top PCB to form a stacked assembly. The stacked assembly is reflowed in a single reflow so that all the solder paste simultaneously or nearly simultaneously melts to bond SMT components to respective PCB boards and to bond respective PCBs to each other.

### BRIEF DESCRIPTION OF THE DRAWINGS

The disclosure is best understood from the following detailed description when read in conjunction with the accompanying drawings and are incorporated into and thus constitute a part of this specification. It is emphasized that, according to common practice, the various features of the drawings are not to-scale. On the contrary, the dimensions of the various features are arbitrarily expanded or reduced for clarity.

FIGS. 1A-D are photographs of a bottom printed circuit board (PCB), a middle PCB, a top PCB and a stacked assembly in accordance with certain implementations.

FIGS. 2A-D are example photographs of a bottom PCB panel, a middle PCB panel, the middle PCB panel stacked on the bottom PCB, a top PCB panel stacked on the middle PCB panel in accordance with certain implementations.

FIG. 3 is a flow diagram of a process for PCB assembly (PCBA) stacking with a single reflow in accordance with certain implementations.

FIGS. 4A-C are example photographs of print transfer images in accordance with certain implementations.

FIG. 5 is a flow diagram of a process with associated devices for PCBA stacking with a single reflow in accordance with certain implementations.

FIG. 6 is a graph of a temperature profile for PCBA stacking with a single reflow in accordance with certain implementations.

FIGS. 7A-G are photographs of gang head pin transfers and gang head pins for PCBA stacking with a single reflow in accordance with certain implementations.

FIG. 8 is a flow diagram of a process for PCBA stacking with gang pin transfer with a single reflow in accordance with certain implementations.

FIG. 9 is a flowchart of a process for PCBA stacking with a single reflow in accordance with certain implementations.

### DETAILED DESCRIPTION

The figures and descriptions provided herein may be simplified to illustrate aspects of the described embodiments that are relevant for a clear understanding of the herein disclosed processes, machines, manufactures, and/or compositions of matter, while eliminating for the purpose of clarity other aspects that may be found in typical similar devices, systems, compositions and methods. Those of ordinary skill may thus recognize that other elements and/or steps may be desirable or necessary to implement the devices, systems, compositions and methods described herein. However, because such elements and steps are well known in the art, and because they do not facilitate a better understanding of the disclosed embodiments, a discussion of such elements and steps may not be provided herein. However, the present disclosure is deemed to inherently include all such elements, variations, and modifications to the described aspects that would be known to those of ordinary skill in the pertinent art in light of the discussion herein.

Embodiments are provided throughout so that this disclosure is sufficiently thorough and fully conveys the scope of the disclosed embodiments to those who are skilled in the art. Numerous specific details are set forth, such as examples of specific aspects, devices, and methods, to provide a thorough understanding of embodiments of the present disclosure. Nevertheless, it will be apparent to those skilled in the art that certain specific disclosed details need not be employed, and that embodiments may be embodied in different forms. As such, the exemplary embodiments set forth should not be construed to limit the scope of the disclosure.

The terminology used herein is for the purpose of describing particular embodiments only and is not intended to be limiting. For example, as used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, steps, operations, elements, and/or components, but do not preclude the presence or addition of one or more other features, steps, operations, elements, components, and/or groups thereof.

The steps, processes, and operations described herein are thus not to be construed as necessarily requiring their respective performance in the particular order discussed or illustrated, unless specifically identified as a preferred or required order of performance. It is also to be understood that additional or alternative steps may be employed, in place of or in conjunction with the disclosed aspects.

Yet further, although the terms first, second, third, etc. may be used herein to describe various elements, steps or aspects, these elements, steps or aspects should not be limited by these terms. These terms may be only used to distinguish one element or aspect from another. Thus, terms such as “first,” “second,” and other numerical terms when used herein do not imply a sequence or order unless clearly indicated by the context. Thus, a first element, step, component, region, layer or section discussed below could be termed a second element, step, component, region, layer or section without departing from the teachings of the disclosure.

The non-limiting embodiments described herein are with respect to a method for printed circuit board (PCB) assembly (PCBA) stacking with a single reflow. The method for PCBA stacking with a single reflow may be modified for a variety of applications and uses while remaining within the spirit and scope of the claims. The embodiments and variations described herein, and/or shown in the drawings, are presented by way of example only and are not limiting as to the scope and spirit. The descriptions herein may be applicable to all embodiments of the method for PCBA stacking in a single reflow.

Described herein is a method for PCBA stacking with a single reflow. In an implementation, the method for PCBA stacking with a single reflow includes depositing solder paste on a bottom PCB and placing surface mount technology (SMT) components on the bottom PCB. A middle PCB is placed on the bottom PCB and solder is deposited on the middle PCB. A top PCB is placed on the middle PCB and solder paste is deposited on the top PCB. SMT components are placed on the top PCB. The stacked bottom PCB with SMT components, middle PCB and top PCB with SMT components are simultaneously subjected to a reflow process. In an implementation, optical inspections may be performed after certain processes. In an implementation, solder deposition may be done using pin transfers. In an implementation, solder deposition may be done using gang pin transfers. In an implementation, pin size may define the deposited volume and size, where package sizes may range from 15 mm square to 008004 package sizes. The single assembly setup described herein improves overall product assembly cycle-time. The techniques described herein advantageously use available SMT equipment. In an implementation, a pick and place device or machine may be used for solder paste deposition using pin transfers or gang pin transfers addition to the picking and placing of PCBs on each other and the picking and placing of the SMT components on certain PCBs. For example, the certain PCBs are the top and bottom PCBs.

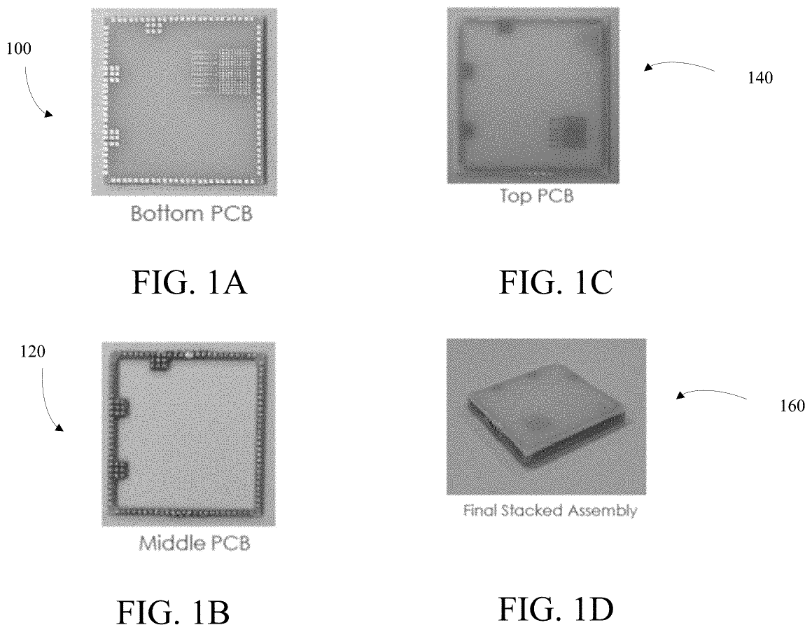

FIGS. 1A-D are photographs of a bottom printed circuit board (PCB) 100, a middle PCB 120, a top PCB 140 and a stacked assembly 160 in accordance with certain implementations. The photographs of the PCBs are illustrative and other types of substrates which contain traces (or lines) and pads to connect points may be used. In an implementation, the illustrative PCBs are of similar size and shape to allow for stacking in accordance with the methods described herein.

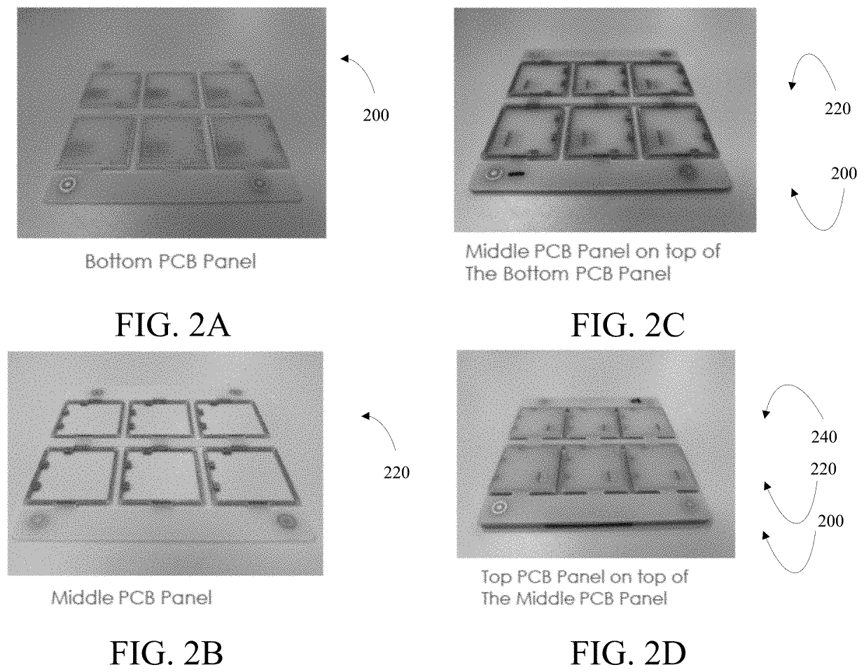

FIGS. 2A-D are example photographs of a bottom PCB panel 200, a middle PCB panel 220, the middle PCB panel 220 stacked on the bottom PCB 200, a top PCB panel 240 stacked on the middle PCB panel 220 (which was previously stacked on the bottom PCB panel 200) in accordance with certain implementations. In an implementation, each of the panels may include multiple PCBs as illustrated in FIGS. 1A-C.

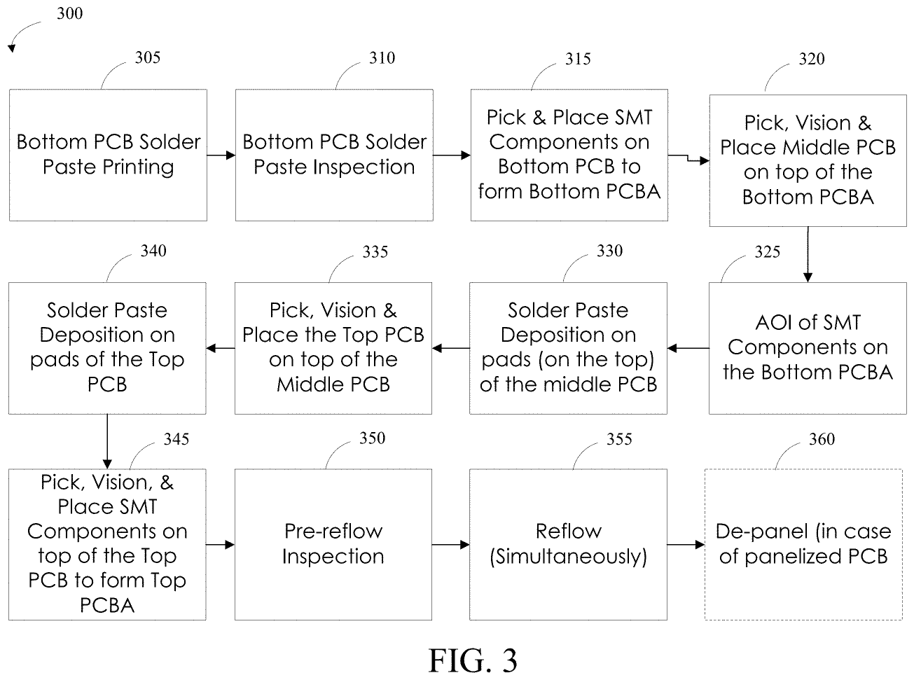

FIG. 3 is a flow diagram of a process 300 for PCBA stacking with a single reflow in accordance with certain implementations. Although three PCBs are used in the illustrative example, the number of middle PCBS may vary depending on application and the like. The process 300 may include depositing 305 solder paste on the bottom PCB such as bottom PCB 100 or bottom PCB panel 200, for example. In an implementation, the solder paste may be printed on the bottom PCB. In an implementation, the solder paste may be printed on the bottom PCB using a stencil. The deposition techniques are illustrative and other deposition techniques may be used. The process 300 may then include inspecting 310 the solder paste deposited on the bottom PCB for proper solder paste deposition.

After solder paste inspection of the bottom PCB, the process 300 may include picking and placing 315 surface mount technology (SMT) components on the bottom PCB to form a bottom PCBA. In an implementation, the SMT components are placed on the top of the bottom PCB. The process 300 may then include picking, seeing and placing 320 a middle PCB on the bottom PCB, where the middle PCB may be the middle PCB 120 or middle PCB panel 220. The process 300 may then include inspecting 325 the placement of the SMT components on the solder paste on the bottom PCB and placement of the middle PCB on the bottom PCB. In an implementation, automated optical inspection (AOI) may be used for inspecting the SMT components to check for catastrophic failure (e.g. a missing component), quality defects and other parameters or characteristics.

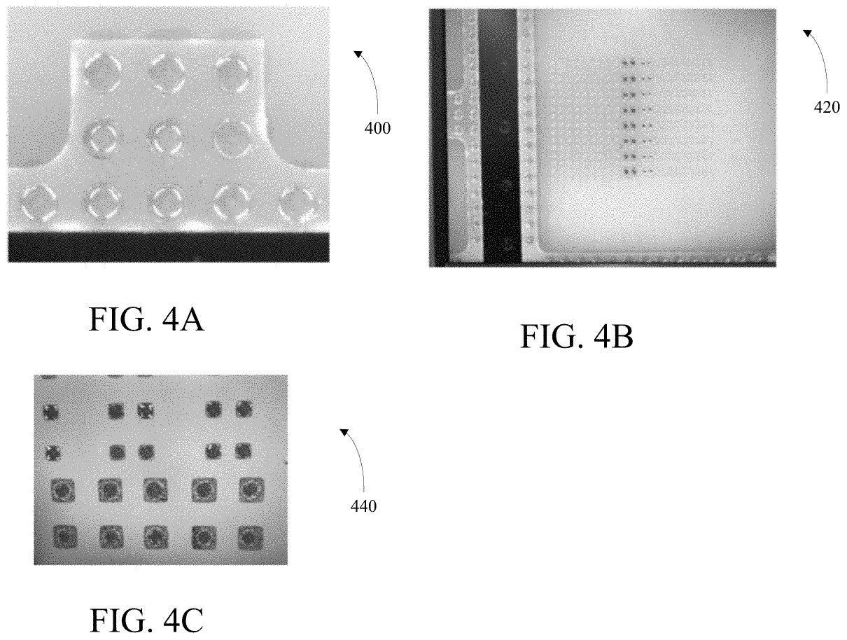

The process 300 may then include depositing 330 solder paste on pads of the middle bottom PCB. In an implementation, the deposition of the solder paste may be done using a pin transfer technique on the middle PCB. The deposition techniques are illustrative and other deposition techniques may be used. In an implementation, vias are not used for the pads on the middle bottom PCB. FIGS. 4A-C are example photographs of transfer images in accordance with certain implementations for 01005 and 008008 size components.

The process 300 may then include picking, seeing and placing 335 a top PCB on the middle PCB, where the top PCB may be the top PCB 140 or top PCB panel 240. The process 300 may then include depositing 340 solder paste on pads of the top PCB. In an implementation, the deposition of the solder paste may be done using a pin transfer technique on the top PCB. The deposition techniques are illustrative and other deposition techniques may be used. After solder paste deposition on the top PCB, the process 300 may include picking, seeing and placing 345 SMT components on the top PCB to form a top PCBA and a stacked assembly such as stacked assembly 160.

The process 300 may include pre-reflow inspecting 350 the stacked assembly for SMT component and PCB placement. In an implementation, AOI may be used for inspecting the SMT components to check for catastrophic failure (e.g. a missing component), quality defects and other parameters or characteristics, and proper placement of each PCB. The process may include reflowing 355 the stacked assembly to melt the solder to create joints between pads, component leads and the multiple PCBs. The stacked assembly is therefore subjected to one reflow process, where the solder simultaneously melts or nearly simultaneously melts in one reflow process. In an implementation where PCB panels are used, the process 300 may include depaneling 360 the stacked assembled PCB panels to form stacked assembled PCBs.

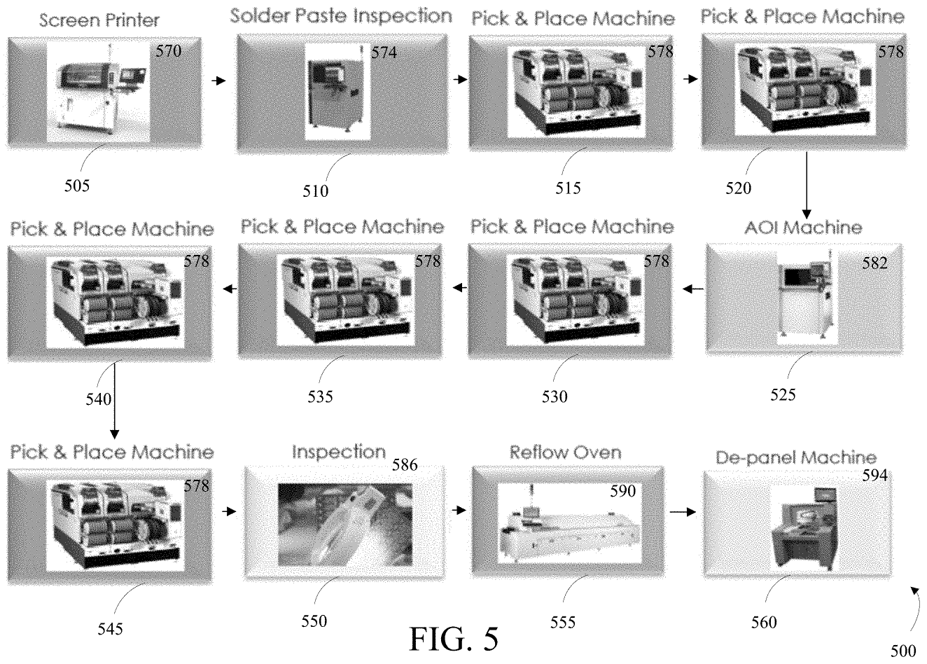

FIG. 5 is a flow diagram of a process 500 with associated devices for PCBA stacking with a single reflow in accordance with certain implementations. Although three PCBs are used in the illustrative example, the number of middle PCBS may vary depending on application and the like. The process 500 may be implemented using a screen printer 570, an inspection device 574, a pick and place device 578, an AOI device 582, an inspection device 586, a reflow oven 590 and a depaneling device 594. In an implementation, the inspection device 574, the inspection device 586 and the AOI device 582 may be one device.

The process 500 may include the screen printer 570 depositing 505 solder paste on the bottom PCB such as bottom PCB 100 or bottom PCB panel 200, for example. In an implementation, the solder paste may be printed on the bottom PCB. In an implementation, the solder paste may be printed on the bottom PCB using a stencil. The deposition techniques are illustrative and other deposition techniques may be used. The process 500 may include the inspection device 574 inspecting 510 the solder paste deposited on the bottom PCB for proper solder paste deposition.

After solder paste inspection of the bottom PCB, the process 500 may include the pick and place device 578 picking and placing 515 SMT components on the bottom PCB to form a bottom PCBA. In an implementation, the pick and place device 578 may place the SMT components on the top of the bottom PCB. The process 500 may then include the pick and place device 578 picking, seeing and placing 520 a middle PCB on the bottom PCB, where the middle PCB may be the middle PCB 120 or middle PCB panel 220. The process 300 may then include the AOI device 582 inspecting 525 the placement of the SMT components on the solder paste on the bottom PCB and placement of the middle PCB on the bottom PCB. In an implementation, the AOI device 582 may be used for inspecting the SMT components to check for catastrophic failure (e.g. a missing component), quality defects and other parameters or characteristics.

The process 500 may then include the pick and place device 578 depositing 530 solder paste on pads of the middle bottom PCB. In an implementation, the pick and place device 578 may be perform deposition by using pin transfer techniques on the middle PCB. The deposition techniques are illustrative and other deposition techniques may be used. In an implementation, vias are not used for the pads on the middle bottom PCB. FIGS. 4A-C are example photographs of transfer images in accordance with certain implementations for 01005 and 008008 size components.

The process 500 may then include the pick and place device 578 picking, seeing and placing 535 a top PCB on the middle PCB, where the top PCB may be the top PCB 140 or top PCB panel 240. The process 500 may then include the pick and place device 578 depositing 540 solder paste on pads of the top PCB. In an implementation, the pick and place device 578 may perform deposition of the solder paste using a pin transfer technique on the top PCB. The deposition techniques are illustrative and other deposition techniques may be used. After solder paste deposition on the top PCB, the process 500 may include the pick and place device 578 picking, seeing and placing 545 SMT components on the top PCB to form a top PCBA and a stacked assembly such as stacked assembly 160.

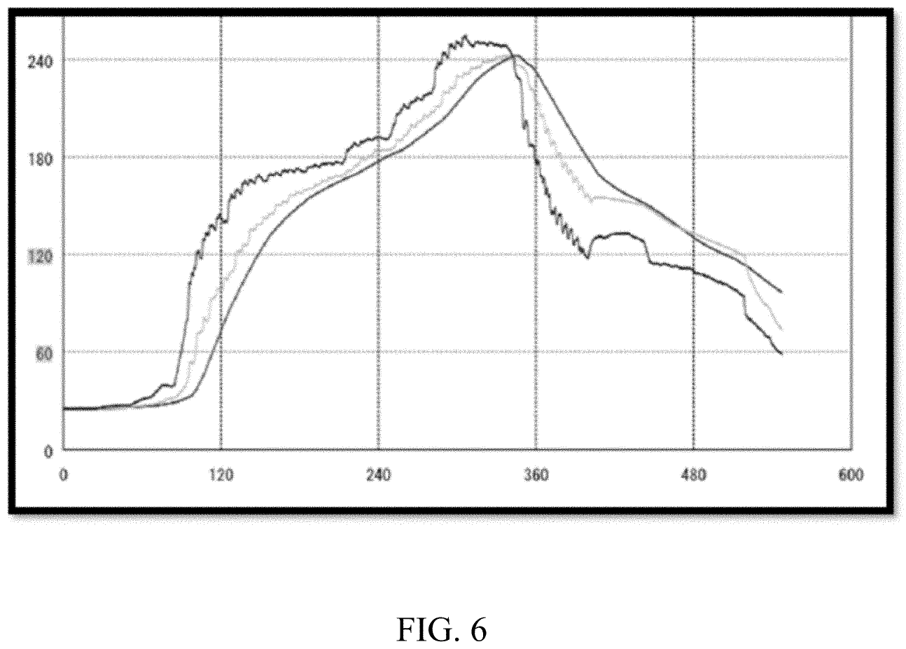

The process 500 may include the inspection device 586 pre-reflow inspecting 550 the stacked assembly for SMT component and PCB placement. In an implementation, AOI may be used for inspecting the SMT components to check for catastrophic failure (e.g. a missing component), quality defects and other parameters or characteristics, and proper placement of each PCB. The process may include using the reflow oven 590 for reflowing 355 the stacked assembly to melt the solder to create joints between pads, component leads and the multiple PCBs. A temperature profile for the reflow oven is shown in FIG. 6. In an implementation, the reflow profile may be a default starting point if recommendations or information is available from the solder paste supplier. In an implementation, a solder paste specification sheet may be used to determine the reflow profile. In an implementation, certain component requirements may require the assembler works at the upper or lower limits of the tolerances specified by the solder paste supplier. That is, both the temperature and the period at this temperature should be verified not to exceed the specifications of the components. In an implementation, the stacked assembly is placed in the reflow oven 590. The stacked assembly is therefore subjected to one reflow process, where the solder simultaneously melts or nearly simultaneously melts in one reflow process. In an implementation where PCB panels are used, the process 500 may include the depaneling device 594 for depaneling 560 the stacked assembled PCB panels to form stacked assembled PCBs.

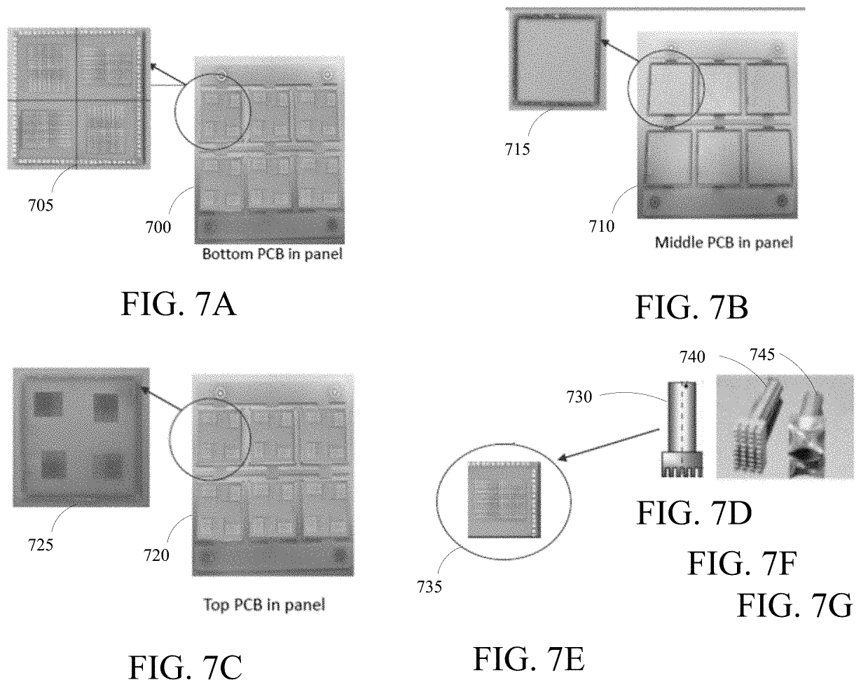

FIGS. 7A-G are photographs of gang head pin transfers and gang head pins for PCBA stacking with a single reflow in accordance with certain implementations. FIG. 7A is a photograph of a bottom PCB panel 700 and a bottom PCB 705 where solder paste has been transferred using a gang pin transfer head. FIG. 7B is a photograph of a middle PCB panel 710 and a middle PCB 715. FIG. 7C is a photograph of a top PCB panel 720 and a top PCB 725 where solder paste has been transferred using a gang pin transfer head. FIG. 7D is a diagram of a gang pin transfer head 730 and FIG. 7E is an associated gang pin transfer pattern 735. In an implementation, the size and shape of the gang pin transfer head 730 may reflect pad size and shape on the PCBs. FIG. 7F is a diagram of a gang pin transfer head 740 and FIG. 7G is a diagram of a gang pin transfer head 745.

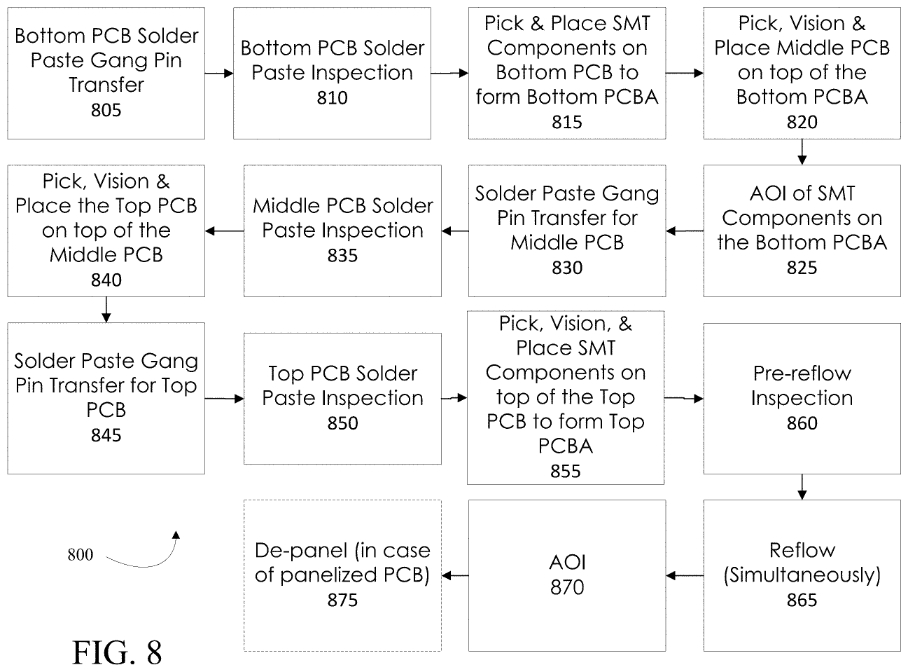

FIG. 8 is a flow diagram of a process 800 for PCBA stacking with gang pin transfer with a single reflow in accordance with certain implementations. Although three PCBs are used in the illustrative example, the number of middle PCBS may vary depending on application and the like. The process 800 may include gang pin transferring 805 solder paste on the bottom PCB such as bottom PCB 100, bottom PCB panel 200, or bottom PCB panel 700, for example. In an implementation, the gang pin transferring 805 may be performed using a gang pin transfer head with a pick and place device, where the gang pin transfer head maybe a gang pin transfer head 730, 740 or 745. The deposition techniques are illustrative and other deposition techniques may be used. The process 800 may then include inspecting 810 the solder paste deposited on the bottom PCB for proper solder paste deposition.

After solder paste inspection of the bottom PCB, the process 800 may include picking and placing 815 surface mount technology (SMT) components on the bottom PCB to form a bottom PCBA. In an implementation, the SMT components are placed on the top of the bottom PCB. The process 800 may then include picking, seeing and placing 820 a middle PCB on the bottom PCB, where the middle PCB may be the middle PCB 120, middle PCB panel 220 or middle PCB panel 710. The process 800 may then include inspecting 825 the placement of the SMT components on the solder paste on the bottom PCB and placement of the middle PCB on the bottom PCB. In an implementation, automated optical inspection (AOI) may be used for inspecting the SMT components to check for catastrophic failure (e.g. a missing component), quality defects and other parameters or characteristics.

The process 800 may then include gang pin transferring 830 solder paste on pads of the middle bottom PCB. The deposition techniques are illustrative and other deposition techniques may be used. In an implementation, vias are not used for the pads on the middle bottom PCB. FIGS. 4A-C are example photographs of transfer images in accordance with certain implementations for 01005 and 008008 size components. The process 800 may then include inspecting 835 the solder paste deposited on the middle PCB for proper solder paste deposition.

The process 800 may then include picking, seeing and placing 840 a top PCB on the middle PCB, where the top PCB may be the top PCB 140, top PCB panel 240 or top PCB panel 720. The process 800 may then include gang pin transferring 845 solder paste on pads of the top PCB. The deposition techniques are illustrative and other deposition techniques may be used. The process 800 may then include inspecting 850 the solder paste deposited on the top PCB for proper solder paste deposition. After inspection of the solder paste deposition on the top PCB, the process 800 may include picking, seeing and placing 855 SMT components on the top PCB to form a top PCBA and a stacked assembly such as stacked assembly 160.

The process 800 may include pre-reflow inspecting 860 the stacked assembly for SMT component and PCB placement. In an implementation, AOI may be used for inspecting the SMT components to check for catastrophic failure (e.g. a missing component), quality defects and other parameters or characteristics, and proper placement of each PCB. The process may include reflowing 865 the stacked assembly to melt the solder to create joints between pads, component leads and the multiple PCBs. The stacked assembly is therefore subjected to one reflow process, where the solder simultaneously melts or nearly simultaneously melts in one reflow process. The process 800 may include inspecting 870 the reflowed stacked assembly for SMT component and PCB bonding. In an implementation, AOI may be used for inspecting the SMT components and each PCB for joint bonding. In an implementation where PCB panels are used, the process 300 may include depaneling 875 the stacked assembled PCB panels to form stacked assembled PCBs.

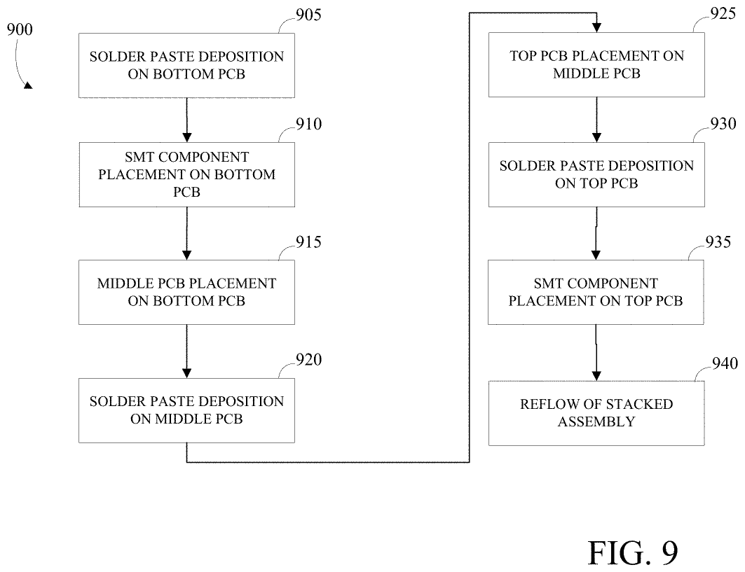

FIG. 9 is a flowchart of a method 900 for PCBA stacking with a single reflow in accordance with certain implementations. The method 900 includes: depositing 905 solder paste on a bottom PCB or bottom PCB panel; picking and placing 910 SMT components on the bottom PCB or bottom PCB panel; picking and placing 915 a middle PCB or middle PCB panel on the bottom PCB or bottom PCB panel; depositing 920 solder paste on the middle bottom PCB or middle PCB panel; picking and placing 925 a top PCB or top PCB panel on the middle PCB or middle PCB panel; depositing 930 solder paste on the top PCB or top PCB panel; picking and placing 935 SMT components on the top PCB or top PCB panel to form a stacked assembly; and reflowing 940 the stacked assembly.

The method 900 includes depositing 905 solder paste on a bottom PCB or bottom PCB panel. In an implementation, solder paste deposition is done by screen printing. In an implementation, solder paste deposition is done by pin transfer. In an implementation, solder paste deposition is done by gang pin transfer. In an implementation, a pick and place device may be used for pin transfer and/or gang pin transfer. In an implementation, the solder paste is deposited on pads. In an implementation, the depositing 905 may include inspecting the bottom PCB or bottom PCB panel after solder paste deposition. In an implementation, an AOI may be used to do the inspecting.

The method 900 includes picking and placing 910 SMT components on the bottom PCB or bottom PCB panel. A bottom PCBA or bottom PCBA panel is formed after placement of the SMT components. In an implementation, a pick and place device may be used for SMT component pick and placement. In an implementation, the picking and placing 910 may include inspecting the SMT component pick and placement. In an implementation, an AOI may be used to do the inspecting.

The method 900 includes picking and placing 915 a middle PCB or middle PCB panel on the bottom PCBA or bottom PCBA panel. In an implementation, the middle PCB or middle PCB panel may be multiple middle PCBs or middle PCB panels. In an implementation, a pick and place device may be used for middle PCB or middle PCB panel pick and placement. In an implementation, the picking and placing 915 may include inspecting the SMT component pick and placement. In an implementation, the picking and placing 915 may include inspecting middle PCB or middle PCB panel pick and placement on the bottom PCBA or bottom PCBA panel. In an implementation, the picking and placing 915 may include inspecting the SMT component pick and placement and inspecting middle PCB or middle PCB panel pick and placement on the bottom PCBA or bottom PCBA panel. In an implementation, an AOI may be used to do the inspecting.

The method 900 includes depositing 920 solder paste on the middle bottom PCB or middle PCB panel. In an implementation, solder paste deposition is done by screen printing. In an implementation, solder paste deposition is done by pin transfer. In an implementation, solder paste deposition is done by gang pin transfer. In an implementation, a pick and place device may be used for pin transfer and/or gang pin transfer. In an implementation, the solder paste is deposited on pads. In an implementation, the depositing 920 may include inspecting the middle PCB or middle PCB panel after solder paste deposition. In an implementation, an AOI may be used to do the inspecting.

The method 900 includes picking and placing 925 a top PCB or top PCB panel on the middle PCB or middle PCB panel. In an implementation, a pick and place device may be used for top PCB or top PCB panel pick and placement. In an implementation, the picking and placing 925 may include inspecting top PCB or top PCB panel pick and placement on the middle PCB or middle PCB panel. In an implementation, an AOI may be used to do the inspecting.

The method 900 includes depositing 930 solder paste on the top PCB or top PCB panel. In an implementation, solder paste deposition is done by screen printing. In an implementation, solder paste deposition is done by pin transfer. In an implementation, solder paste deposition is done by gang pin transfer. In an implementation, a pick and place device may be used for pin transfer and/or gang pin transfer. In an implementation, the solder paste is deposited on pads. In an implementation, the depositing 930 may include inspecting the top PCB or top PCB panel after solder paste deposition. In an implementation, an AOI may be used to do the inspecting.

The method 900 includes picking and placing 935 SMT components on the top PCB or top PCB panel to form a stacked assembly. A top PCBA or top PCBA panel is formed after placement of the SMT components. In an implementation, a pick and place device may be used for SMT component pick and placement. In an implementation, the picking and placing 935 may include inspecting the SMT component pick and placement. In an implementation, the picking and placing 915 may include inspecting top PCBA or top PCBA panel pick and placement on the middle PCB or middle PCB panel. In an implementation, the picking and placing 935 may include inspecting the SMT component pick and placement and inspecting top PCBA or top PCBA panel pick and placement on the middle PCB or middle PCB panel. In an implementation, an AOI may be used to do the inspecting.

The method 900 includes reflowing 940 the stacked assembly in a single reflow. The reflowing 940 simultaneously or nearly simultaneously melts the solder paste to form bonds or joint bonds between the SMT components and each of the PCB boards and between each of the respective PCB boards in one reflow process or operation. In an implementation, the reflowing 940 may include inspecting of the stacked assembly after reflow. In an implementation, an AOI may be used to do the inspecting. In an implementation, the reflowing 940 may include pre-reflow inspecting of the stacked assembly. In an implementation, an AOI may be used to do the inspecting. In an implementation, when PCB panels may be used, the reflowing 940 includes depaneling the reflowed stacked assembly to obtain PCBs.

The construction and arrangement of the methods as shown in the various exemplary embodiments are illustrative only. Although only a few embodiments have been described in detail in this disclosure, many modifications are possible (e.g., variations in sizes, dimensions, structures, shapes and proportions of the various elements, values of parameters, mounting arrangements, use of materials and components, colors, orientations, etc.). For example, the position of elements may be reversed or otherwise varied and the nature or number of discrete elements or positions may be altered or varied. Accordingly, all such modifications are intended to be included within the scope of the present disclosure. The order or sequence of any process or method steps may be varied or re-sequenced according to alternative embodiments. Other substitutions, modifications, changes, and omissions may be made in the design, operating conditions and arrangement of the exemplary embodiments without departing from the scope of the present disclosure.

Although the figures may show a specific order of method steps, the order of the steps may differ from what is depicted. Also two or more steps may be performed concurrently or with partial concurrence. Such variation will depend on the software and hardware systems chosen and on designer choice. All such variations are within the scope of the disclosure. Likewise, software implementations could be accomplished with standard programming techniques with rule-based logic and other logic to accomplish the various connection steps, processing steps, comparison steps, and decision steps.

While the disclosure has been described in connection with certain embodiments, it is to be understood that the disclosure is not to be limited to the disclosed embodiments but, on the contrary, is intended to cover various modifications and equivalent arrangements included within the scope of the appended claims, which scope is to be accorded the broadest interpretation so as to encompass all such modifications and equivalent structures as is permitted under the law.

What is claimed is:

1. A method for printed circuit board (PCB) assembly (PCBA) stacking with a single reflow comprising:
depositing solder paste on a bottom PCB;
picking and placing surface mount technology (SMT) components on the bottom PCB;
picking and placing a middle PCB on the bottom PCB;
depositing solder paste on the middle PCB;
picking and placing a top PCB on the middle PCB;
depositing solder paste on the top PCB;
picking and placing SMT components on the top PCB to form a stacked assembly; and
reflowing the stacked assembly in a single reflow.

2. The method of claim 1, wherein the bottom PCB is a bottom PCB panel, the middle PCB is a middle PCB panel, and the top PCB is a top PCB panel, the method further comprising:
depaneling the stacked assembly to form stacked assembly PCBs.

3. The method of claim 1, wherein the depositing solder paste on the bottom PCB, the depositing solder paste on the middle bottom PCB, and the depositing solder paste on the top PCB is done with a pin transfer process using a pick and place device.

4. The method of claim 1, wherein the depositing solder paste on a bottom PCB, the depositing solder paste on the middle bottom PCB, and the depositing solder paste on the top PCB is done with a gang pin transfer process using a pick and place device.

5. The method of claim 1, wherein after one or more of the depositing solder paste on a bottom PCB, the picking and placing SMT components on the bottom PCB, the picking and placing a middle PCB on the bottom PCB, the depositing solder paste on the middle PCB, the picking and placing a top PCB on the middle PCB, the depositing solder paste on the top PCB, and the picking and placing SMT components on the top PCB to form a stacked assembly, the method further comprising:
inspecting one or more of solder paste deposition, PCB placement, and SMT components placement.

6. The method of claim 1, wherein one or more of the depositing solder paste on a bottom PCB, the picking and placing SMT components on the bottom PCB, the picking and placing a middle PCB on the bottom PCB, the depositing solder paste on the middle bottom PCB, the picking and placing a top PCB on the middle PCB, the depositing solder paste on the top PCB, and the picking and placing SMT components on the top PCB to form a stacked assembly is performed using a pick and place machine.

7. The method of claim 1, wherein all solder paste simultaneously or nearly simultaneously melts to bond SMT components to respective PCB boards and to bond respective PCBs to each other.

8. A system for printed circuit board (PCB) assembly (PCBA) stacking with a single reflow, the system comprising:
a deposition device configured to deposit solder paste on a bottom PCB;
a pick and place machine configured to:
pick and place surface mount technology (SMT) components on the bottom PCB;
to deposit solder paste on a middle PCB;
to pick and place a top PCB on the middle PCB;
to deposit solder paste on a top PCB;
to pick and place SMT components on the top PCB to form a stacked assembly; and
a reflow oven configured to reflow the stacked assembly in a single reflow.

9. The system of claim 8, wherein the deposition device is the pick and place machine.

10. The system of claim 9, wherein the pick and place is configured to use a pin transfer device to deposit the solder paste on the bottom PCB, on the middle bottom PCB, and on the top PCB.

11. The system of claim 9, wherein the pick and place is configured to use a gang pin transfer device to deposit the solder paste on the bottom PCB, on the middle bottom PCB, and on the top PCB.

12. The system of claim 8, wherein the bottom PCB is a bottom PCB panel, the middle PCB is a middle PCB panel, and the top PCB is a top PCB panel, the system further comprising:
a depaneling device configured to depanel the stacked assembly to form stacked assembly PCBs.

13. The system of claim 8, further comprising:
an automated optical inspective device configured to inspect one or more of solder paste deposition on the bottom PCB, SMT components placement on the bottom PCB, the middle PCB placement on the bottom PCB, solder paste deposition on the middle PCB, the top PCB placement on the middle PCB, solder paste deposition on the top PCB, and SMT components placement on the top PCB, the stacked assembly, and the reflowed stacked assembly.

14. The system of claim 8, wherein all solder paste simultaneously or nearly simultaneously melts to bond SMT components to respective PCB boards and to bond respective PCBs to each other.

15. A method for printed circuit board (PCB) assembly (PCBA) stacking with a single reflow comprising:
transferring solder paste on a bottom PCB;
forming a bottom PCBA by placing surface mount technology (SMT) components on the bottom PCB;
stacking a middle PCB on the bottom PCBA to form an intermediate stack;
transferring solder paste on the middle PCB;
stacking a top PCB on the intermediate stack;
transferring solder paste on the top PCB;
forming a stacked assembly by placing SMT components on the top PCB; and
reflowing the stacked assembly in a single reflow, wherein all solder paste simultaneously or nearly simultaneously melts to bond SMT components to respective PCB boards and to bond respective PCBs to each other.

16. The method of claim 15, wherein the bottom PCB is a bottom PCB panel, the middle PCB is a middle PCB panel, and the top PCB is a top PCB panel, the method further comprising:
depaneling the stacked assembly to form stacked assembly PCBs.

17. The method of claim 15, wherein the transferring solder paste on the bottom PCB, the transferring solder paste on the middle bottom PCB, and the transferring solder paste on the top PCB is done using a pin transfer device in cooperation with a pick and place device.

18. The method of claim 15, wherein the transferring solder paste on a bottom PCB, the transferring solder paste on the middle bottom PCB, and the transferring solder paste on the top PCB is done using a gang pin transfer device in cooperation with a pick and place device.

19. The method of claim 15, further comprising:
inspecting one or more of solder paste deposition, PCB placement, and SMT components placement.

20. The method of claim 15, wherein the transferring solder paste on a bottom PCB, the forming a bottom PCBA by placing surface mount technology (SMT) components on the bottom PCB, the forming an intermediate stack by placing a middle PCB on the bottom PCBA, the transferring solder paste on the middle PCB, forming another intermediate stack by placing a top PCB on the intermediate stack, the transferring solder paste on the top PCB, and the forming a stacked assembly by placing SMT components on the top PCB is performed using a pick and place machine.
